(19) United States
(12) Patent Application Publication
(10) Pub. No.: US 2006/0077646 A1
(43) Pub. Date: Apr. 13, 2006

(54) Combined varistor and LC filter device

(75) Inventors: Jin Mo Ahn, Kyungsangnam-do (KR); Sung Sik Shin, Kyungsangnam-do (KR); Kwang Soo Park, Kyungsangnam-do (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/150,287

(22) Filed: Jun. 13, 2005

(30) Foreign Application Priority Data
Oct. 11, 2004 (KR) 10-2004-80928

(51) Int. Cl. H05K 1/16

(52) U.S. Cl. 361/793; 361/794; 333/185

(57) ABSTRACT

Disclosed herein is a combined varistor and LC filter device in which both a varistor function of protecting circuits by absorbing surge voltage and an electromagnetic interference filter function of improving radiation characteristics are implemented in a single chip, thus having reduced mounting area. The combined device includes a body which acts as an insulator at voltages below a predetermined level, and the resistance of which decreases rapidly at voltages above a predetermined level. Inductance patterns constituting an LC resonant circuit, capacitance patterns and ground patterns are implemented in the body in a multilayer structure. The combined device operates as an LC filter at a low voltage and operates as a varistor at a high voltage.

### RELATED APPLICATION

The present application is based on, and claims priority from, Korean Application Number 2004-80928, filed Oct. 11, 2004, the disclosure of which is incorporated by reference herein in its entirety.

### BACKGROUND OF THE INVENTION

1. Field of the Invention

The present invention relates generally to a combined device used for mobile communication equipment and, more particularly, to a combined varistor and LC filter device that can have both a varistor function of protecting circuits by absorbing surge voltage and an electromagnetic interference filter function of improving radiation characteristics by filtering out signals other than signals in a set band.

2. Description of the Related Art

Most mobile communication equipment is provided with a varistor for protecting circuits from overvoltage or static electricity flowing in from the outside, and with a high frequency ElectroMagnetic Interference (EMI) suppression filter.

FIG. 1 shows an example of the conventional circuit construction of a varistor and an EMI suppression filter. The varistor 11 is provided between a signal line IN-OUT, through which a signal is transferred, and the ground. When voltage above a predetermined level is applied, the resistance of the varistor 11 decreases rapidly and, therefore, the varistor 11 absorbs the corresponding overvoltage. Furthermore, an EMI filter 12, including an inductor L connected to the signal line IN-OUT in series, and capacitors Cl and C2 provided between both ends of the inductor L and the ground, is used as the EMI suppression filter. The EMI filter 12 passes the signals in an LC resonant frequency band, and attenuates other noise components by bypassing them to the ground.

The varistor 11 is a device the resistance of which varies with applied voltage and which has remarkable nonlinear voltage/current characteristics, and functions as an insulator in a normal state, the resistance value of which decreases rapidly when voltage exceeding an appropriate value is applied to the device. Due to such characteristics, the varistor 11 is widely used to protect other semiconductor devices by absorbing surge voltage when the surge voltage is applied.

The varistor 11 has excellent nonlinear voltage/current characteristics, and is manufactured by mixing powdered ceramic raw material, containing zinc oxide ZnO as a main component and a plurality of additives, and by baking the object formed of the powdered ceramic raw material to increase surge absorbing capability. In the varistor 11 manufactured in this manner, energy barriers are formed at boundary barrier layers due to the energy levels of impurities existing at the boundaries between zinc oxide particles in the varistor 11 and, therefore, the excellent voltage/current nonlinearity results.

The EMI filter 12 may be implemented using RC resonant circuits, rather than the above-described circuit.

The EMI filter 12 is generally manufactured through a process of printing L and C components, or R and C components inside and outside a body composed of dielectric material, such as ceramic, in a multilayer structure.

However, recently, to meet the demand for multiple functionality and compactness of mobile communication equipment, research into decreasing the size of devices used for mobile communication equipment has been widely conducted. In addition, attempts to combine various functions in a single chip are conducted.

Although the EMI filter and the varistor are commonly used on the front ends of most mobile communication equipment, the EMI filter and the varistor are conventionally manufactured as individual components described above and are assembled in the mobile communication equipment, so that the conventional components are problematic in that separate mounting areas are required, and interference between individual components can occur.

### SUMMARY OF THE INVENTION

Accordingly, the present invention has been made keeping in mind the above problems occurring in the prior art, and an object of the present invention is to provide a combined varistor and LC filter device that implements an EMI filter function of improving radiation characteristics and a varistor function of protecting circuits from overvoltage in a single chip, thus being able to be mounted in a small area.

In order to accomplish the above object, the present invention provides a combined varistor and LC filter device, including a body mainly composed of zinc oxide, the zinc oxide functioning as an insulator at voltages below a predetermined level and the resistance of zinc oxide decreasing rapidly at voltages above a predetermined level; outer ground electrodes formed on the outer surface of the body and connected to a ground; input and output electrodes formed on the outer surface of the body to input and output signals; inductance patterns formed inside the body to have predetermined lengths, the respective ends of each of the inductance patterns being connected to the input and output electrodes; two or more inner ground patterns formed in predetermined planes inside the body and connected to the outer ground electrodes; and one or more capacitance patterns formed in predetermined planes between the inner ground patterns and parallel to the inner ground patterns, and selectively connected to the input and output electrodes.

Furthermore, in the combined varistor and LC filter device in accordance with the present invention, the inductance patterns are a plurality of conductive patterns formed in different planes, the plurality of conductive patterns being electrically connected to each other through a via hole.

Furthermore, in the combined varistor and LC filter device in accordance with the present invention, each of the inductance patterns is formed in a spiral shape or a meandering shape.

Furthermore, in the combined varistor and LC filter device in accordance with the present invention, when voltage above a predetermined level is applied to the input and output electrodes, the combined device functions as a varistor that allows the applied voltage to be absorbed into the ground as a resistance value of the body decreases.

Furthermore, in the combined varistor and LC filter device in accordance with the present invention, when a voltage signal below a predetermined level is applied to the input and output electrodes, the combined device resonates at a resonant frequency depending on capacitance formed between the capacitance patterns and the inner ground patterns, thereby functioning as a filter that passes a specific frequency band therethrough.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a circuit showing the construction of part of the front end of mobile communication equipment;

FIG. 2 is a perspective view showing the outer structure of a combined varistor and LC filter device in accordance with an embodiment of the present invention;

FIG. 3 is an exploded perspective view showing the inner structure of the combined varistor and LC filter device in accordance with the embodiment of the present invention;

FIG. 4a is a diagram showing the equivalent circuit of the combined varistor and LC filter device in accordance with the embodiment of the present invention;

FIG. 4b is a diagram showing the equivalent circuit of the combined varistor and LC filter device in accordance with the embodiment of the present invention when a normal voltage is applied;

FIG. 4c is a diagram showing the equivalent circuit of the combined varistor and LC filter device in accordance with the embodiment of the present invention when overvoltage is applied;

FIG. 5a is a graph showing the measured characteristics of a filter in a combined varistor and LC filter device in accordance with the embodiment of the present invention;

FIG. 5b is a graph showing the measured Electro-Static Discharge (ESD) characteristics of the combined varistor and LC filter device in accordance with the embodiment of the present invention;

FIG. 6 is a perspective view showing the external structure of a combined varistor and LC filter device having a multiple terminal array structure in accordance with another embodiment of the present invention; and

FIG. 7 is an exploded perspective view showing the inner structure of the multiple terminal array structure of FIG. 6.

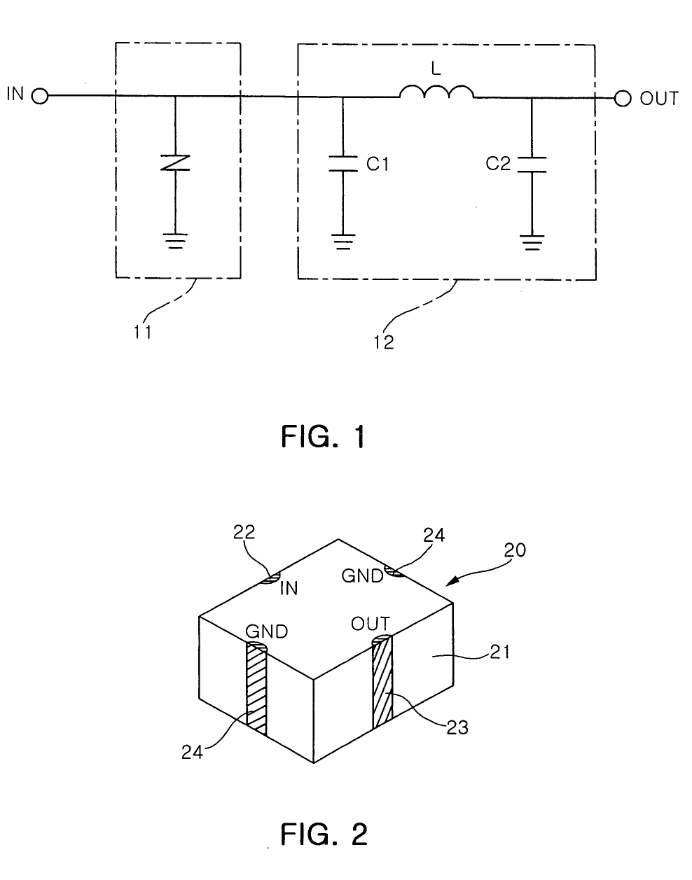

### DESCRIPTION OF THE PREFERRED EMBODIMENTS

Preferred embodiments of the present invention are described in detail with reference to the accompanying drawings below. In the following description and the accompanying drawings, details of well-known functions and constructions that depart from the gist of the present invention or that have little relationship to the present invention are omitted, and the same reference numeral is used for components that perform the same function.

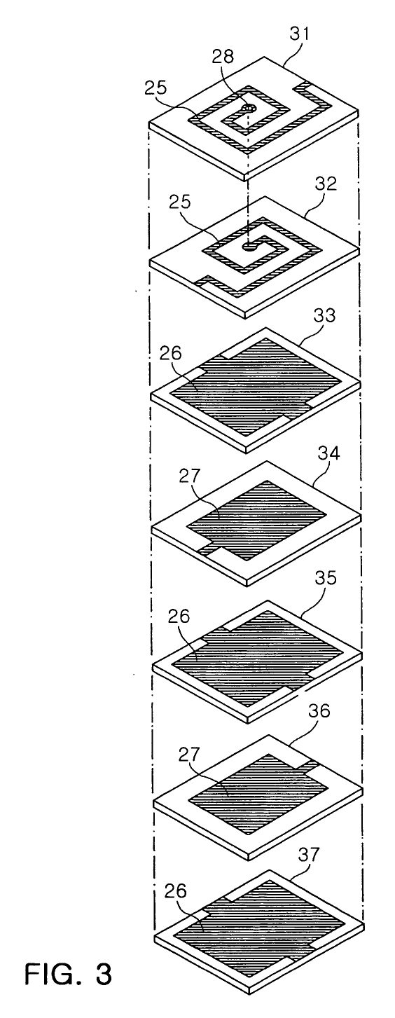

FIG. 2 is a perspective view showing the outer structure of a combined varistor and LC filter device in accordance with an embodiment of the present invention. FIG. 3 is an exploded perspective view showing the inner structure of the combined varistor and LC filter device in accordance with the embodiment of the present invention.

Referring to FIG. 2, the combined varistor and LC filter device 20 in accordance with the embodiment of the present invention includes a body 21 mainly composed of zinc oxide ZnO, which functions as an insulator at voltages below a predetermined level and the resistance of which decreases rapidly at voltages above a predetermined level, and outer ground electrodes 24 formed on the outer surface of the body and connected to the ground, and input and output electrodes 22 and 23 formed on the outer surface of the body to input and output signals.

Furthermore, referring to FIGS. 2 and 3, the combined varistor and LC filter device 20 in accordance with the embodiment of the present invention includes inductance patterns 25 formed inside the body, configured to have predetermined lengths, and each having ends connected to the input and output electrodes, two or more inner ground patterns 26 formed in a predetermined plane inside the body to be connected to the outer ground electrodes 24, and one or more capacitance patterns 27 formed in a predetermined plane positioned between the inner ground patterns 26 and parallel to the inner ground patterns 26, and connected to the input electrode 22 or the output electrode 23.

The inductance patterns 25 may be formed in a straight-line shape, a meandering shape or a spiral shape, and have predetermined lengths. Sufficient inductance can be realized in a smaller area when the inductance patterns 25 are formed in a meandering shape or a spiral shape rather than in a straight-line shape. In this way, the size of the device can be further reduced.

Furthermore, the inductance patterns 25 can be implemented by forming conductive patterns, each of which has a straight-line shape, a meandering shape or a spiral shape, on different planes disposed inside the body 21 and electrically connecting them to each other through a via hole 28. In this way, sufficient inductance can be realized in a smaller area, so that the size of the device can be further reduced. The realized inductance can be calculated from the lengths of the inductance patterns 25 and the dielectric constant of the body 21.

The capacitance patterns 27 generate predetermined capacitance between the inner ground patterns 26 that are adjacent and parallel to each other. In this case, the generated capacitance can be calculated from the areas of the capacitance patterns 27 facing the ground electrodes 26, the gaps between the ground electrodes 26 and the capacitance patterns 27, and the dielectric constant of the material constituting the body 21.

Accordingly, in the case of the above-described combined varistor and LC filter device 20 in accordance with the embodiment of the present invention, when cutoff frequencies are set, a resonant frequency, capacitance and inductance are determined based on the set cutoff frequencies, so that a desired EMI LC filter can be implemented by designing the lengths of the inductance patterns 25, the areas of the capacitance patterns 27 and the gaps between the ground electrodes 26 and the capacitance patterns 27.

Furthermore, in the body 21 of the above-described combined varistor and LC filter device 20 in accordance with the embodiment of the present invention, zinc oxide ZnO, which has excellent nonlinear voltage/current characteristics and large surge absorbing capability, is used as a main component. A plurality of additives may be mixed with the zinc oxide ZnO in order to improve the characteristics of the device.

The above-described body 21 has voltage/current nonlinearity because energy barriers are formed at boundary barrier layers due to the energy levels of impurities existing at boundaries between its zinc oxide particles.

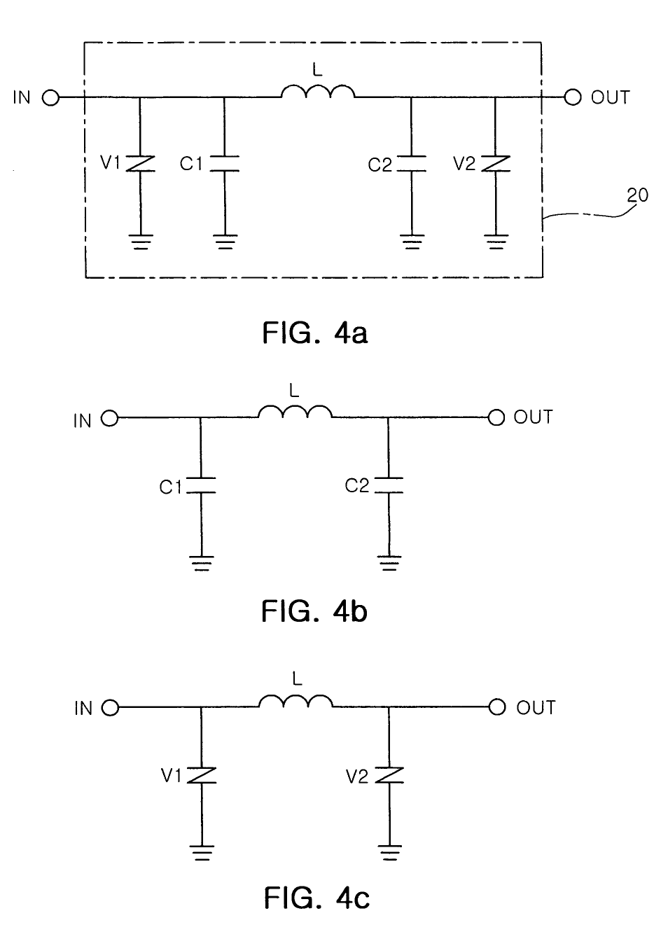

The equivalent circuit of the above-described combined varistor and LC filter device 20 in accordance with the embodiment of the present invention can be illustrated as shown in FIG. 4a.

That is, an inductor L is connected in series between input and output terminals IN and OUT that respectively input and output electrical signals having predetermined frequency and voltage, and capacitors C1 and C2 are connected between both ends of the inductor L and the ground, so that an LC resonance circuit is implemented. Furthermore, varistors V1 and V2 are connected between the input terminal IN and the ground and between the output terminal OUT and the ground.

The operation of the combined varistor and LC filter device 20 is divided into two cases: the case of the application of voltages above a predetermined level and the case of the application of voltages below a predetermined level.

In the first case, when voltage above a boundary barrier level, which is formed by the energy levels of impurities existing inside the zinc oxide ZnO, is applied to the body 21 through the input and output terminals 22 and 23, the resistance value of the body 21 decreases rapidly and, therefore, the applied voltage is absorbed into the body 21. That is, as the resistance value of the body 21 decreases rapidly, the device 20 operates as a varistor, as shown in FIG. 4c.

In the second case, when voltage below a boundary barrier level is applied to the body 21 through the input and output terminals 22 and 23, the body 21 composed of the zinc oxide ZnO functions as an insulator, similar to ceramic material.

Accordingly, the inductance patterns 25, the inner ground patterns 26 and the capacitance patterns 27 formed inside the body 21 are electrically connected to each other, so that the LC resonant circuit of FIG. 4b is implemented. As a result, the LC resonant circuit resonates at a resonant frequency depending on an L component formed by the inductance patterns 25 and a C component formed between the capacitance patterns and the inner ground pattern 27, thus operating as a filter that passes signals in a predetermined band therethrough and attenuates signals in the other bands.

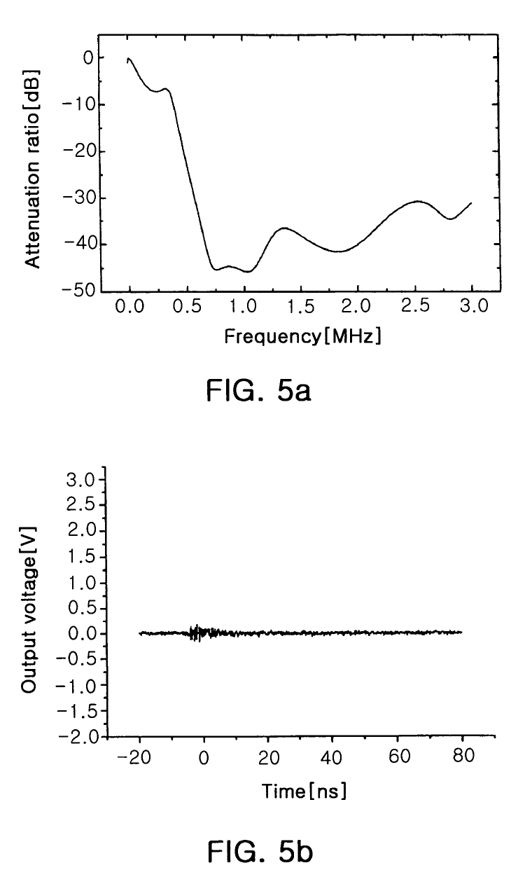

FIGS. 5a and 5b are graphs showing the operational characteristics of the combined varistor and LC filter device in accordance with the embodiment of the present invention. FIG. 5a is a graph showing measured attenuation ratios according to frequency when an electrical signal having a voltage below a predetermined level is applied. In this graph, it can be seen that the combined device 20 functions as a low-pass filter that passes frequency signals below 0.5 MHz therethrough and attenuates high frequency signals above 0.5 MHz. FIG. 5b is a graph showing measured output voltage according to time when an ESD voltage of 8 kV is applied. In this graph, it can be seen that the output voltage is maintained at 0 V upon the application of overvoltage and, as a result, circuits connected to the output terminal can be protected by the absorption of the overvoltage.

The combined varistor and LC filter device in accordance with an embodiment of the present invention may be implemented in a multiple terminal array structure in which two or more varistors and two or more LC filters are combined in parallel in a single chip.

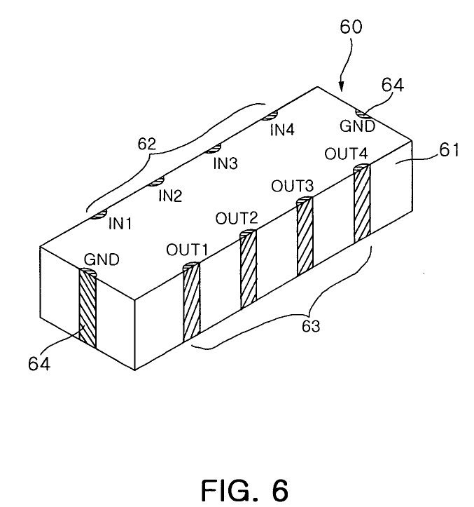

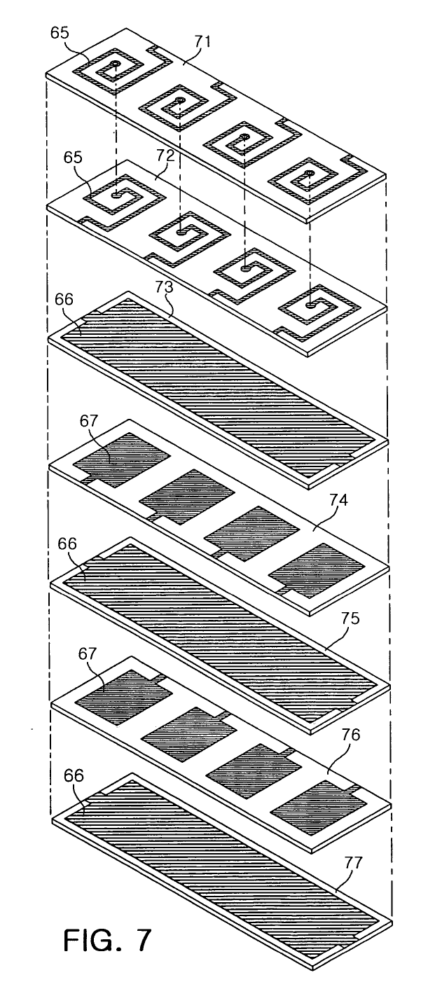

FIGS. 6 and 7 are a perspective view and an exploded perspective view, respectively, showing a combined varistor and LC filter device having a multiple terminal array structure, in accordance with another embodiment of the present invention.

Referring to FIGS. 6 and 7, the combined varistor and LC filter device 60 is formed by providing a body 61 that is mainly composed of zinc oxide ZnO and functions as an insulator at voltages below a predetermined level, and the resistance of which decreases rapidly at voltages above a predetermined level. Outer ground electrodes 64 are formed on two opposite side surfaces having relatively short lengths in a body 61 having a rectangular hexahedron shape. Two or more input and output electrodes 62 and 63 are formed on two opposite side surfaces having relatively long lengths. The input electrodes 62 are electrically insulated from each other, and the output electrodes 63 are also not electrically connected to each other.

Furthermore, as shown in FIG. 7, inside the combined device, a plurality of inductance patterns 65, which are connected to the plurality of input and output electrodes 62 and 63, and a plurality of capacitance patterns 67, which are connected to the plurality of input or output electrodes 62 and 63, are formed parallel to each other on a plurality of sheets 71 to 77 that are stacked in order from top to bottom and are composed of zinc oxide ZnO, thus forming a body 61. Ground patterns 66 are formed on the sheets 73, 75 and 77, respectively, that are positioned above and below each of the pluralities of capacitance patterns 67. In this case, the ground patterns 66 are formed in sufficient sizes to correspond to the sizes of the plurality of capacitance patterns 67 positioned above and/or below them.

The inductance patterns 65, the ground patterns 66 and the capacitance patterns 67 have the same functions as the inductance patterns 25, the ground patterns 26 and the capacitance patterns 27 shown in FIG. 3.

In this case, the plurality of inductance patterns 65 is not interconnected, and the plurality of inductance patterns 67 is also not interconnected.

Accordingly, a plurality of combined varistor and LC filter devices, each of which operates independently, is formed inside a single chip, so that the mounting area in a set requiring the plurality of combined varistor and LC filter devices can be reduced.

As described above, the present invention can implement both a varistor function of protecting circuits from overvoltage and a filter function of improving radiation characteristics in a single chip, thus reducing the number of components mounted in mobile communication equipment that requires both a varistor and a filter. Furthermore, the present invention can realize a compact set due to the reduction of a mounting area.

Furthermore, the present invention can achieve the effects of reducing interference between components and the number of Surface Mount Technology (SMT) points by reducing the number of assembled components.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A combined varistor and LC filter device, comprising:
a body mainly composed of zinc oxide, the zinc oxide functioning as an insulator at voltages below a predetermined level and resistance of zinc oxide decreasing rapidly at voltages above a predetermined level;
outer ground electrodes formed on an outer surface of the body and connected to a ground;
input and output electrodes formed on an outer surface of the body to input and output signals;
inductance patterns formed inside the body to have predetermined lengths, respective ends of each of the inductance patterns being connected to the input and output electrodes;
two or more inner ground patterns formed in predetermined planes inside the body and connected to the outer ground electrodes; and
one or more capacitance patterns formed in predetermined planes between the inner ground patterns and parallel to the inner ground patterns, and selectively connected to the input and output electrodes.

2. The combined varistor and LC filter device as set forth in claim 1, wherein the inductance patterns are a plurality of conductive patterns formed in different planes, the plurality of conductive patterns being electrically connected to each other through a via hole.

3. The combined varistor and LC filter device as set forth in claim 1, wherein each of the inductance patterns is formed in a spiral shape or a meandering shape.

4. The combined varistor and LC filter device as set forth in claim 1, wherein, when voltage above a predetermined level is applied to the input and output electrodes, the combined device functions as a varistor that allows the applied voltage to be absorbed into the ground as a resistance value of the body decreases.

5. The combined varistor and LC filter device as set forth in claim 1, wherein, when a voltage signal below a predetermined level is applied to the input and output electrodes, the combined device resonates at a resonant frequency depending on capacitance formed between the capacitance patterns and the inner ground patterns, thereby functioning as a filter that passes a specific frequency band therethrough.

6. A combined varistor and LC filter device, comprising:
a body configured to have a rectangular hexahedron shape, and mainly composed of zinc oxide, the zinc oxide functioning as an insulator at voltages below a predetermined level and resistance of the zinc oxide decreasing rapidly at voltages above a predetermined level;
outer ground electrodes formed on opposite side surfaces and having relatively short lengths among outer surfaces of the body, and connected to a ground;
input and output electrodes formed on opposite side surfaces and having relatively long lengths among the outer surfaces of the body to input and output signals;
a plurality of inductance patterns disposed to be parallel to predetermined planes inside the body, and configured to have predetermined lengths, respective ends of the inductance patterns being connected to the input and output electrodes;
two or more inner ground patterns formed parallel to each other above and below predetermined planes under the plurality of inductance patterns and connected to the outer ground electrodes; and
a plurality of capacitance patterns formed in a predetermined planes between the inner ground patterns to be positioned parallel to each other, and selectively connected to the input and output electrodes;
wherein the combined varistor and LC filter device is formed in a multiple terminal array structure.
